(19) United States
(12) Patent Application Publication
(10) Pub. No.: US 2026/0033348 A1
(43) Pub. Date: Jan. 29, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Gi Jeong Kim, Gyeonggi-do (KR); Kwang Soo Sang, Incheon (KR); Dong Su Ryu, Incheon (KR)

(73) Assignee: Amkor Technology Singapore Holding Pte. Ltd., Singapore (SG)

(21) Appl. No.: 18/784,836

(22) Filed: Jul. 25, 2024

(51) Int. Cl. H01L 23/495; H01L 21/48; H01L 21/56; H01L 23/00; H01L 23/31

(52) U.S. Cl. CPC H01L 23/49548; H01L 21/4828; H01L 21/565; H01L 23/3107; H01L 24/48; H01L 24/32; H01L 24/73; H01L 2224/32245; H01L 2224/48249; H01L 2224/73265; H01L 2924/35121

(57) ABSTRACT

In one example, an electronic device, comprises a substrate comprising a first side and a second side opposite to the first side, wherein the substrate comprises dimples on the first side of the substrate, an electronic component over the first side of the substrate, an encapsulant over the first side of the substrate and covering a lateral side of the electronic component, and a first interconnect in the encapsulant and coupled to the electronic component and the substrate. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIGS. 1A, 1B, and 1C show, respectively, a cross-sectional view, a bottom view, and enlarged portion of a top view of an example electronic device.

FIGS. 2A to 2H show cross-sectional views of an example method for manufacturing an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to a mechanical coupling or an electrical coupling.

### DESCRIPTION

In one example, an electronic device, comprises a substrate comprising a first side and a second side opposite to the first side, wherein the substrate comprises dimples on the first side of the substrate, an electronic component over the first side of the substrate, an encapsulant over the first side of the substrate and covering a lateral side of the electronic component, and a first interconnect in the encapsulant and coupled to the electronic component and the substrate.

In another example, an electronic device comprises a substrate comprising a first side and a second side opposite to the first side, a paddle, and a lead, wherein the substrate comprises dimples on the first side of the substrate, an electronic component over the first side of the substrate over the paddle, an encapsulant over the first side of the substrate and covering a lateral side of the electronic component, and a first interconnect in the encapsulant and coupled to the electronic component and the lead.

In a further example, a method to manufacture an electronic device comprises providing a substrate comprising a first side and a second side opposite to the first side, etching dimples on the first side of the substrate, wherein the dimples are located on a first portion of the first side of the substrate, and a second portion of the first side of the substrate is free of the dimples, attaching an electronic component to the first side of the substrate, providing a first interconnect coupled to the electronic component and the substrate, and providing an encapsulant over the first side of the substrate and covering a lateral side of the electronic component.

Other examples are included in the present disclosure. Such examples may be found in the figures, in the claims, or in the description of the present disclosure.

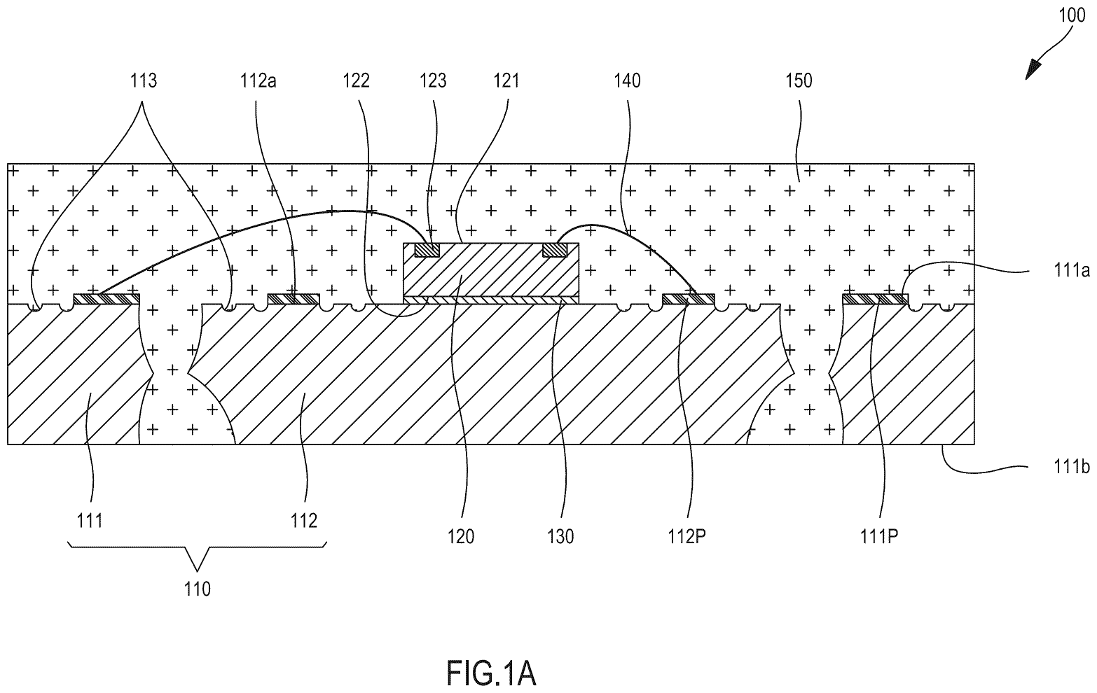

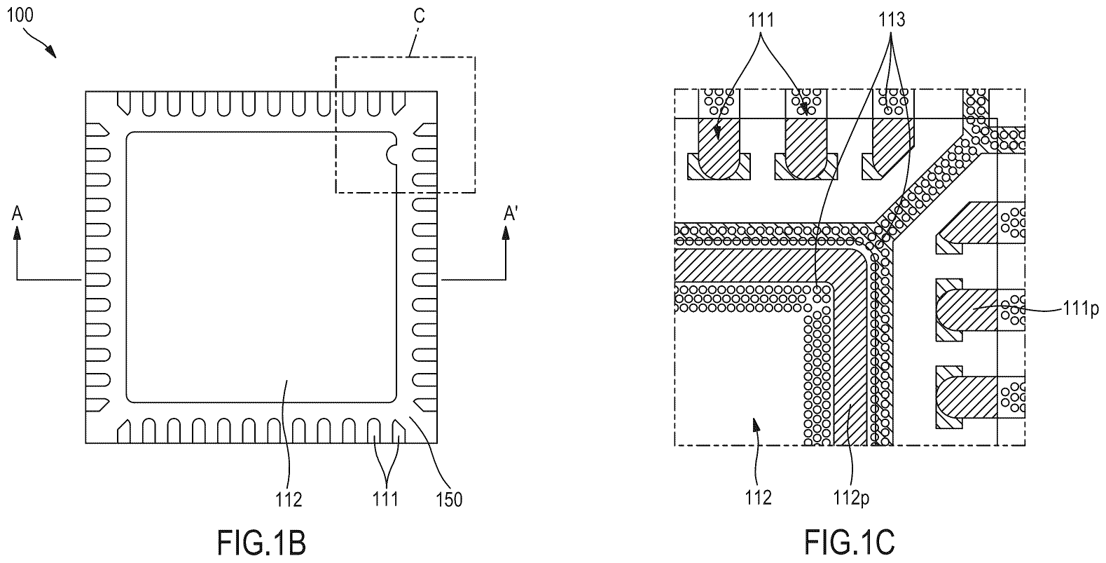

FIG. 1A shows a cross-sectional view of example electronic device 100. In the example shown in FIG. 1A, electronic device 100 can comprise substrate 110, electronic component 120, die attach material 130, interconnects 140, and encapsulant 150. FIG. 1B shows a bottom view of example electronic device 100. The cross-sectional view of FIG. 1A is taken along line A-A′ in FIG. 1B. FIG. 1C shows an enlarged view of the top side of substrate 110 in area C of FIG. 1B.

With combined reference to FIGS. 1A, 1B, and 1C, substrate 110 can comprise leads 111 and paddle 112. Leads 111 and paddle 112 can comprise dimples 113 provided on first side 110a of substrate 110. Leads 111 can comprise lead inward terminal 111a and lead outward terminal 111b. Paddle 112 can comprise paddle inward terminal 112a. Lead inward terminal 111a can comprise lead plating 111P. Paddle 112 can comprise paddle plating 112P. Interconnects 140 can be coupled to lead plating 111P or paddle plating 112P of substrate 110. Dimples 113 can be between paddle plating 112P or lead plating 111P and electronic component 120, or paddle plating 112P or lead plating 111P can be between electronic component 120 and dimples 113. In some examples, dimples 113 can be at an outer periphery of substrate 110. Dimples 113 can be arranged in a ring pattern on the first side of substrate 110. In some examples, dimples 113 can be arranged in a row pattern or a column pattern. In some examples, dimples 114 are located on a first portion of the first side of substrate 110, and a second portion of the first side of substrate is free of dimples 113. In some examples, dimples are on lead inward terminal 111a adjacent to lead plating 111P.

Electronic component 120 can comprise first side 121 and second side 122 opposite first side 121. Electronic component 120 can comprise contact pads 123 on first side 121. Interconnects 140 can be coupled between contact pads 123 and leads 111. In some examples, one or more of the interconnects 140 can be coupled between one or more contact pads 123 and paddle 112. In some examples, electronic device 100 can comprise substrate 110 having a first side and a second side opposite to the first side. Substrate 110 can comprise dimples 113 on the first side of substrate 110. Electronic component 120 can be over the first side of substrate 110. Encapsulant 150 can be over the first side of substrate 110 and can cover a lateral side of electronic component 120. Interconnect 140 can be in encapsulant 150 and can be coupled to electronic component 120 and substrate 110.

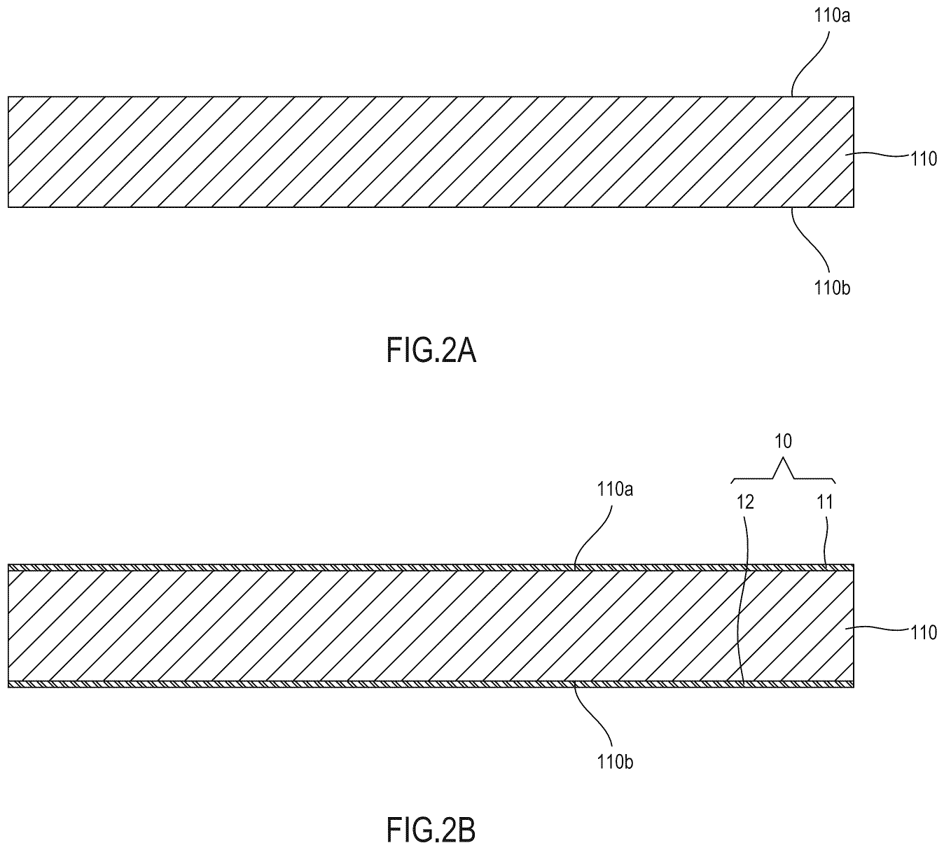

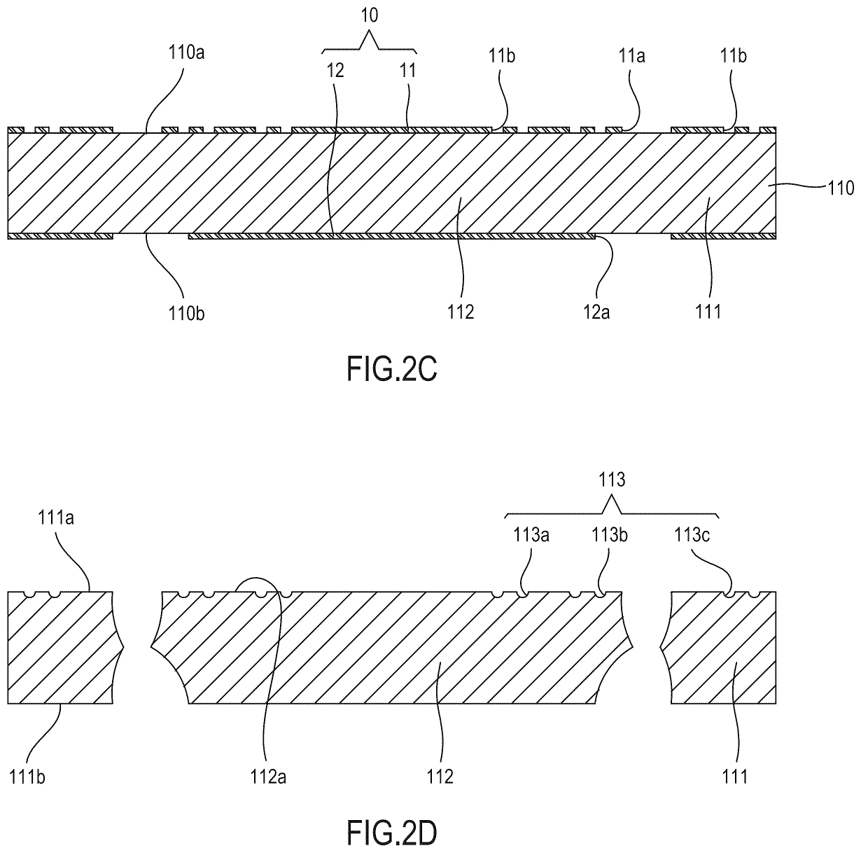

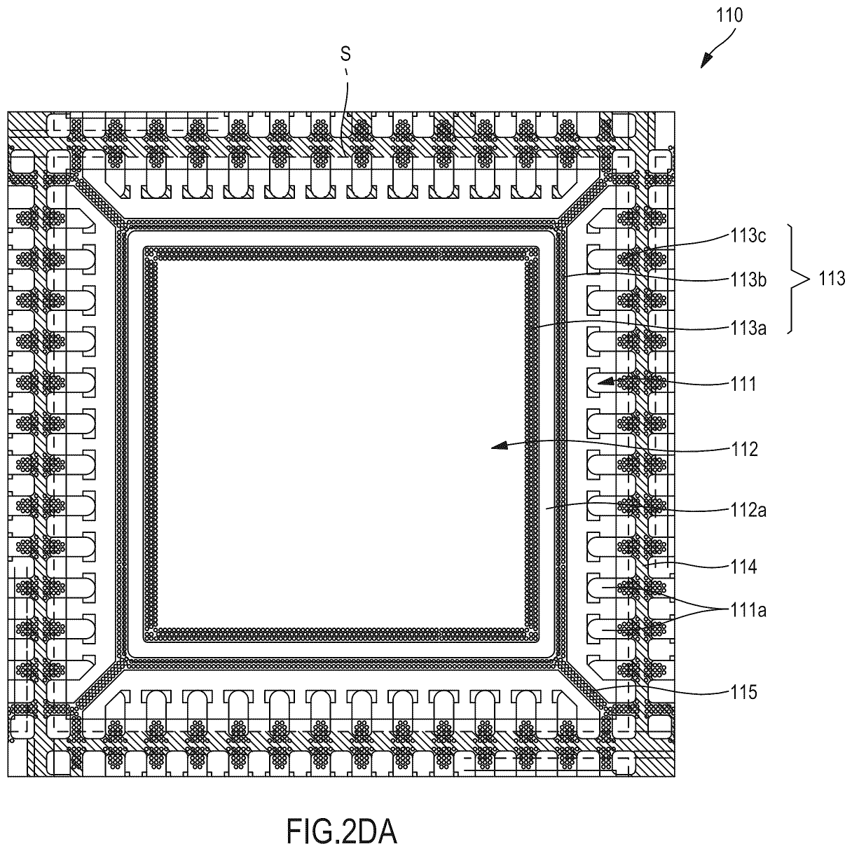

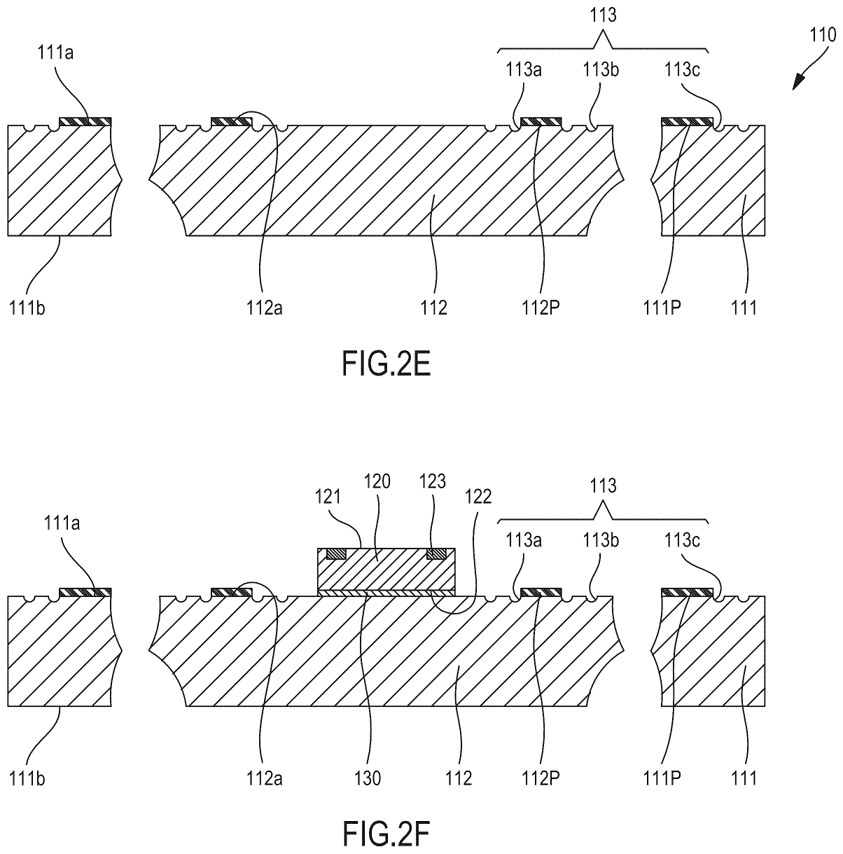

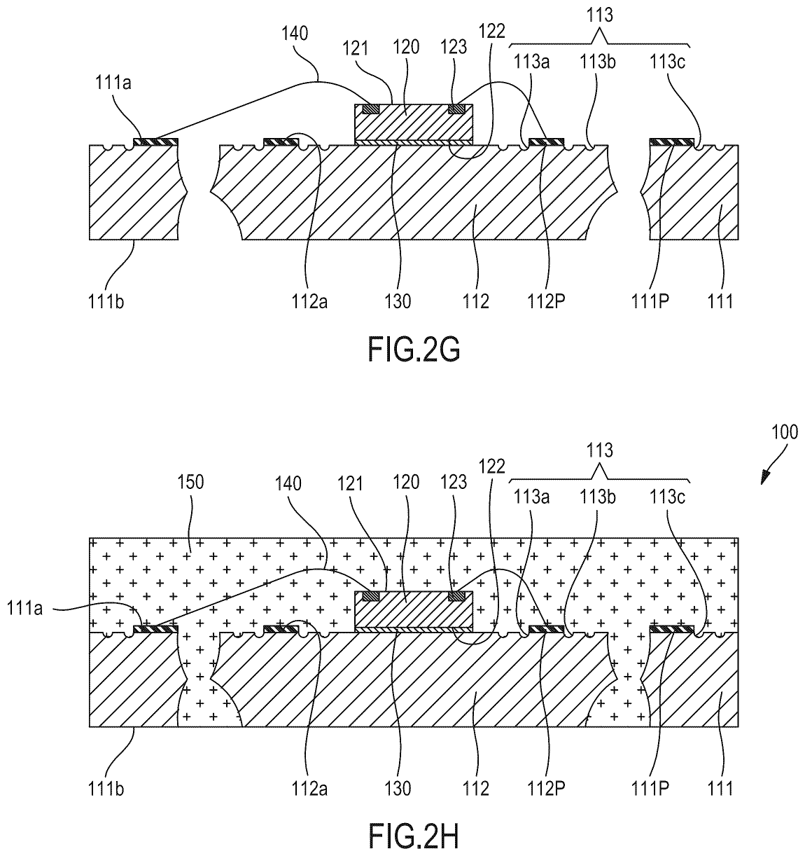

FIGS. 2A to 2H show cross-sectional views of an example method for manufacturing example electronic device, such as electronic device 100 in FIG. 1. FIG. 2A shows a cross-sectional view of electronic device 100 at an early stage of manufacture. In the example shown in FIG. 2A, substrate 110 is provided. In some examples, substrate 110 can be a planar plate, and in some examples substrate 110 can comprise a substantially planar plate. In some examples, substrate 110 can comprise or be referred to as a leadframe, a substrate, a metal substrate, a conductor, or a conductive plate. Substrate 110 can include traces, leads, tie-bars, terminal leads, and so on. Substrate 110 can be made of metal or metal alloy. For example, substrate 110 can be made of copper (Cu), a Cu alloy such as a Cu material that also includes at least one of nickel (Ni), silicon (Si), phosphorus (P), or titanium (Ti), an iron-nickel alloy, or a copper/stainless steel/copper (Cu/SUS/Cu) clad metal. Substrate 110 can have first side 110a and second side 110b opposite to first side 110a. First side 110a of substrate 110 or second side 110b of substrate 110 can be substantially flat or planar. In accordance with various examples, the surface of substrate 110 can be treated with a chemical to prevent oxidation, can be plated with a pre plating frame (PPF) of tin, nickel, palladium, or gold plated on first side 110a substrate 110 and second side 110b of substrate 110, or can be provided with a plating layer comprising silver as an example. The plating can be selectively plated only on a portion of first side 110a of substrate 110. In some examples, the plating layer provided on first side 110a of substrate 110 can be silver and can have thickness range from 1.78 micrometers (μm) to 7.62 μm. In some examples, the plating layer provided on first side 110a of substrate 110 can be a non-silver material such as tin, nickel, palladium, or gold and can have a thickness range from 7.62 μm to 15.24 μm.

FIG. 2B shows a cross-sectional view of electronic device 100 at a later stage of manufacture. In the example shown in FIG. 2B, photoresist 10 can be provided on first side 110a of substrate 110 or second side 110b of substrate 110. In some examples, photoresist 10 can comprise first photoresist 11 provided on first side 110a of substrate 110 and second photoresist 12 provided on second side 110b of substrate 110.

In accordance with various examples, photoresist 10 can be a liquid or film type and can be attached to first side 110a of substrate 110 or second side 110b of substrate 110. In some examples, photoresist 10 can be provided on first side 110a of substrate 110 or second side 110b of substrate 110 by coating. First photoresist 11 can contact or cover first side 110a of substrate 110, and second photoresist 12 can contact or cover second side 110b of substrate 110. The thickness of each of first photoresist 11 and second photoresist 12 can range from approximately 30 μm to approximately 100 μm.

FIG. 2C shows a cross-sectional view of electronic device 100 at a later stage of manufacture. In the example shown in FIG. 2C, photoresist 10 can be patterned. For example, a mask can be provided over and partially covering photoresist 10. Photoresist 10 can be patterned through exposure, and after patterning photoresist 10 the mask can be removed.

Patterned photoresist 10 can cover regions of substrate 110 where paddle 112 and leads 111 are to be provided, while not covering regions to be etched. Patterned photoresist 10 can have spaced-apart exposing regions 11a and exposing regions 12a located between paddle 112 and leads 111 and between multiple leads 111. It is noted that in FIG. 2C, leads 111 and paddle 112 have not yet been formed, but the regions of substrate 110 corresponding to the locations where leads 111 and paddle 112 will eventually be formed are labeled for purposes of illustration. Paddle 112 will be located at the center region of substrate 110, and leads 111 will be positioned adjacent to paddle 112 along a lateral side of substrate 110. In some examples, first photoresist 11 can include exposing regions 11a, exposing first side 110a of substrate 110, and second photoresist 11 can include exposing regions 12a exposing second side 110b of substrate 110. Exposing regions 11a and 12a can be used to form leads 111 and paddle 112 and to separate the formed leads 111 from one another, and to separate the formed paddle 112 from the formed leads 111. In some examples, the size or width of exposing regions 11a can be approximately 0.1 mm (100 μm) to approximately 0.3 mm (300 μm), and the size or width of exposing regions 12a can be approximately 0.25 mm (250 μm) to approximately 0.45 mm (450 μm).

In accordance with various examples, first photoresist 11 can comprise holes or micro holes 11b exposing first side 110a of substrate 110. The location of at least a first group of the micro holes 11b corresponds to a region of substrate 110 where paddle 112 is to be formed, and the locations of at least a second group of the micro holes 11b corresponds to a region of substrate 110 where leads 111 are to be formed. Micro holes 11b can be spaced apart from each other in a first direction or row direction or row pattern, or in a second direction or column direction or column pattern. In some examples, the width or diameter of micro holes 11b can be approximately 0.04 mm (40 μm) to approximately 0.08 mm (80 μm) as a width or diameter range, and the pitch or separation distance between adjacent micro holes 11b can be approximately 0.015 mm (15 μm) to approximately 0.05 mm (50 μm) as a pitch range.

FIGS. 2D and 2DA show a cross-sectional view and a top view, respectively, of electronic device 100 at a later stage of manufacture. In the example shown in FIGS. 2D and 2DA, substrate 110 can be patterned through photoresist 10. On first side 110a of substrate 110, the region exposed through exposing region 11a of first photoresist 11 can be removed by etching, and the regions exposed through micro holes 11b can be etched and partially removed.

Second side 110b of substrate 110 can be patterned by removing the region exposed through exposing region 12a of second photoresist 12 by etching. In substrate 110, the region removed through exposing region 11a of first photoresist 11 and the region removed through exposing region 12a of second photoresist 12 can at least partially overlap one another and can extend to sufficient respective depths to provide an opening between first side 110a of substrate 110 and second side 110b of substrate 110. After patterning substrate 110, photoresist 10 can be removed from substrate 110.

Substrate 110 can be patterned to separate paddle 112 from leads 111, and to separate multiple leads 111 from each other. In some examples, paddle 112 can have a square or rectangular shape in a top-down view, generally having four lateral sides, and leads 111 can be spaced apart from the four lateral sides of paddle 112. Paddle 112 can be provided with paddle inward terminal 112a having a square ring shape or ring pattern in a top-down view on first side 110a of substrate 110. Paddle inward terminal 112a can be spaced apart from the lateral edge of paddle 112. In some examples, paddle inward terminal 112a can comprise or be referred to as pads or terminal leads. For example, paddle inward terminal 112a can be a ground terminal. In some examples, one or more of leads 111 can be connected to paddle 112. Leads 111 connected to paddle 112 can be ground terminals.

Leads 111 can be spaced apart from one or more of the four lateral sides of paddle 112 and can be arranged in rows or columns. Leads 111 can comprise lead inward terminal 111a on first side 110a of substrate 110, and lead outward terminals 111b on second side 110b of substrate. As shown in FIG. 2DA, leads 111 can be connected to each other with connection bar 114. Connection bar 114 can comprise a generally square-shaped ring coupled to leads 111. Leads 111 can comprise lead inward terminal 111a and lead outward terminals 111b. In some examples, lead inward terminals 111a and lead outward terminals 111b can comprise or be referred to as pads or lands. For example, lead inward terminals 111a and lead outward terminals 111b can be signal terminals. In some examples, connection bar 114 can be coupled to paddle 112 through tie bar 115. Tie bar 115 can extend from four corners of paddle 112 to connection bar 114.

Substrate 110 can be partially etched through micro holes 11b of first photoresist 11 to provide dimples 113 on first side 110a of substrate 110. For example, dimples 113 can be provided on paddle 112 and leads 111. Dimples 113 can comprise first dimples 113a on first side 110a of substrate 110 located inside or interior to paddle inward terminal 112a. Dimples 113 can comprise second dimples 113b on first side of substrate 110a located outside or exterior to paddle inward terminal 112a. Dimples 113 can comprise third dimples 113c on first side 111a of substrate 110 located on leads 111. Third dimples 113c can be at an outer periphery of substrate 110.

In general, first dimples 113a can be provided in a square or rectangular ring shape inside or interior to paddle inward terminal 112a and adjacent to paddle inward terminal 112a. For example, paddle inward terminal 112a can be between first dimples 113a and leads 111. Second dimples 113b can be provided in a square or rectangular ring shape outside or exterior to paddle inward terminal 112a and adjacent to paddle inward terminal 112a. For example, second dimples 113b can be between paddle inward terminal 112a and leads 111. Third dimples 113c can be provided near lead inward terminal 111a and near connection bar 114. In some examples, dimples 113 can be provided on tie bar 115.

In some examples, the widths or diameters of dimples 113 as measured at first surface 110a of substrate 110 can range from approximately 30 μm to approximately 50 μm, the pitch or separation distance between adjacent dimples 113 can range from 30 μm to 50 μm, and the depth of dimples 113 can range from approximately 30 μm to approximately 50 μm, or the depth of dimples 113 can be half the dimple width or diameter. In such cases, the depth of dimples 113 can range from approximately 15 μm to approximately 25 μm. In some examples, paddle 112 can have an area of approximately 1 millimeter (mm) by 1 mm to approximately 10 mm by 10 mm. Dimples 113 can be provided on substrate 110 during etching of substrate. In some examples, dimples 113 can be provided on substrate 110 without requiring or involving copper (Cu) roughening or surface treating of top side 110a of substrate 110 and without requiring any corresponding Cu plating of the roughened or treated surface of top side 110a of substrate 110. As a result, any separate process for surface treatment of top side 110a or substrate 1110 can be omitted, which tends to decrease manufacturing time and costs. In some examples, dimples 113 have widths comprising a width range, and dimples 113 have pitches comprising a pitch range In some examples, the width range is the same as the pitch range.

FIG. 2E shows a cross-sectional view of electronic device 100 at a later stage of manufacture. In the example shown in FIG. 2E, plating 111P, 112P can be provided on first side 110a of substrate 110. Paddle plating 112P can be provided to cover paddle inward terminal 112a of substrate 110, and lead plating 111P can be provided to cover lead inward terminal 111a. Paddle plating 112P can be in contact with and electrically connected to paddle inward terminal 112a, and lead plating 111P can be in contact with and electrically connected to lead inward terminal 111a. Paddle plating 112P and lead plating 111P can facilitate conductive connection between paddle inward terminal 112a and lead inward terminal 111a, respectively, with interconnects 140. Paddle plating 112P can have a ring shape in a plane and can be located between first dimples 113a and second dimples 113b. Lead plating 111P can be located inside third dimples 113a in a plane, such that third dimples 113a are located between lead plating 111P and the outer lateral sides of leads 111.

In some examples, paddle plating 112P and lead plating 111P can be provided by electroless plating, electroplating, or sputtering, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). In some examples, paddle plating 112P and lead plating 111P can comprise silver (Ag) and/or tin (Sn). The thicknesses of paddle plating 112P and lead plating 111P can range from approximately 1.78 μm to approximately 7.62 μm.

In some examples, paddle plating 112P and lead plating 111P can each comprise a pre-plated frame (PPF). Paddle plating 112P and lead plating 111P can comprise nickel-palladium-gold (Ni/Pd/Au), or an alloy of silver and gold, sequentially coated to cover substrate 110. When paddle plating 112P and lead plating 111P are each PPF, the thickness of paddle plating 112P and lead plating 111P can range from approximately 0.256 μm to approximately 0.653 μm, and inner side 111a and outer side 111b of substrate 111 can be entirely plated.

FIG. 2F shows a cross-sectional view of electronic device 100 at a later stage of manufacture. In the example shown in FIG. 2F, electronic component 120 can be provided on paddle 112 of substrate 110.

Electronic component 120 can comprise first side 121 and second side 122. Second side 122 of electronic component 120 can be the opposite of first side 121. In some examples, first side 121 of electronic component 120 can comprise or be referred to as an active side, and second side 122 of electronic component 120 can comprise or be referred to as an inactive side or back side. Electronic component 120 can comprise a side wall connecting first side 121 and second side 122. In some examples, electronic component 120 can comprise or be referred to as a die, a chip, or a package (e.g., electronic component 120 could comprise a package having one or more encapsulant die).

Second side 122 of electronic component 120 can be coupled to first side 110a of substrate 110 on paddle 112 through die attach material 130. Electronic component 120 can be attached to the central region of first side 110a of substrate 110 on paddle 112 using die attach material 130. Electronic component 120 can be attached to paddle 112 to be located inside first dimples 113a on first side 110a of paddle 112. Stated differently, first dimples 113a can be located adjacent to one or more of the lateral side walls of electronic component 120. In some examples, first dimples 113a can be located about the perimeter of electronic component 120 or can surround electronic component 120.

For example, after die attach material 130 is applied or attached to first side 110a of substrate 110 on paddle 112, pick and place equipment can pick up electronic component 120 and place electronic component 120 on the top of die attach material 130 to attach electronic component 120 to substrate 110. When electronic component 120 is seated on substrate 110, second side 110b of substrate 110 can be located on the lower side of substrate 110, and electronic component 120 can be seated on the upper side of substrate 110. Die attach material 130 can be provided on paddle 112 of substrate 110 by a coating method such as spin coating, doctor blade coating, casting, painting, spray coating, slot die coating, curtain coating, slide coating, or knife over edge coating, a printing method such as screen printing, pad printing, gravure printing, flexography printing, or offset printing, or an inkjet printing method, an intermediate technology between coating and printing, or can be provided by direct attachment of an adhesive film or an adhesive tape. In some examples, die attach material 130 can comprise or be referred to as an adhesive, an adhesive layer, or an adhesive film.

Electronic component 120 can comprise contact pads 123 provided on first side 121 of electronic component 120. Contact pads 123 can be input/output terminals of electronic component 120. Contact pads 123 of electronic component 120 can be provided on first side 121 of electronic component 120 to be spaced apart from each other in a row or column direction. Contact pads 123 of electronic component can comprise or be referred to as die pads or bond pads of electronic component 120. In some examples, contact pads 123 can be bond pads exposed through a silicon oxide film (SiO2) or a silicon nitride film (SiN), or redistribution layer pads exposed by a dielectric material. In some examples, contact pads 123 can comprise an electrically conductive material, such as, aluminum, copper, an aluminum alloy, a copper alloy, or other metallic material.

In some examples, the overall thickness of electronic component 120 can range from approximately 50 μm to approximately 350 μm. In some examples, the area or footprint of electronic component 120 can be smaller than an area of paddle 112, and can range from approximately 0.8 mm by 0.8 mm (800 μm by 800 μm) to approximately 6 mm by 6 mm.

FIG. 2G shows a cross-sectional view of electronic device 100 at a later stage of manufacture. In the example shown in FIG. 2G, contact pads 123 of electronic component 120 and substrate 110 can be electrically connected through interconnects 140.

In some examples, interconnects 140 can comprise or be referred to as wires, leads, tabs, or clips. In some examples, interconnects 140 can comprise copper coated with gold, copper, aluminum, or palladium. Interconnects 140 provide electrical coupling between substrate 110 and electronic component 120. Electronic component 120 can be electrically connected to paddle inward terminal 112a through one or more first interconnects 140 and paddle plating 112P, and can be electrically connected to lead inward terminal 111a through one or more second interconnects 140 and lead plating 111P. In some examples, the thicknesses of interconnects 140 can range from approximately 15 μm to approximately 30 μm. In some examples, one or more interconnects 140 can electrically couple paddle inward terminal 112a and lead inward terminal 111a. For example, interconnects 140 can be bonded to paddle plating 112P and lead plating 111P to electrically couple paddle 112 and leads 111. In some examples, leads 111 electrically connected to paddle 112 can be ground terminals.

In some examples, contact pads 123 and first side 121 of electronic component 120 can be oriented toward substrate 110 and electronic component 110 can be mounted on substrate 110 as a flip chip. For example, electronic component 120 can be coupled to paddle plating 112P and lead plating 111P of substrate 110 by bumps, tin/lead (SnPb) bumps, leadfree bumps, copper phosphorus (CuP), stud bumps, pillars, or posts.

FIG. 2H shows a cross-sectional view of electronic device 100 at a later stage of manufacture. In the example shown in FIG. 2H, encapsulant 150 can be provided to cover substrate 110 and electronic component 120.

Encapsulant 150 can comprise or be referred to as a body or a molding. For example, encapsulant 150 can comprise an epoxy mold compound, a resin, an organic polymer with inorganic fillers, a curing agent, a catalyst, a coupling agent, a colorant, or a flame retardant, and can be provided by compression molding, transfer molding, liquid body molding, and vacuum lamination, paste printing, or film-assisted molding. In some examples, encapsulant 150 can be provided to cover or be in contact with first side 110a of substrate 110, and can cover first side 121 of electronic component 120 and lateral sides or sidewalls of electronic component 120, and interconnects 140. In some examples, the thickness of encapsulant 150 can range from approximately 127 μm to approximately 800 μm. Encapsulant 150 can protect electronic component 120 and interconnects 140. In accordance with various examples, dimples 113 on first side 110a of substrate 110 increase the surface area of substrate 110 for bonding with encapsulant 150 (i.e. dimps 113 increase the surface area of the interface between substrate 110 and encapsulant 15), which tends to increase bonding strength between substrate 110 and encapsulant 150.

After providing encapsulant 150, substrate 110 and encapsulant 150 can be sawed and separated into individual electronic devices 100. A sawing process for separating into individual electronic devices 100 can be referred to as a singulation or sawing process. For example, substrate 110 and encapsulant 150 can be separated into individual electronic devices 100 by removing some regions using a diamond wheel, laser beam, or an etching process. For example, substrate 110 can be sawed along device outline S in FIG. 2DA. Connection bar 114 of substrate 110 can be removed from electronic device 100 during a singulation process. In electronic device 110, leads 111 of substrate 110 can be electrically separated from one another.

Electronic device 100 can comprise substrate 110, electronic component 120, die attach material 130, interconnects 140, and encapsulant 150. Since substrate 110 includes dimples 113 on first side 110a of substrate 110, the bonding area between substrate 110 and encapsulant 150 can be increased to increase bonding strength. Since paddle 112 of substrate 110 is provided with first dimples 113a and second dimples 113b inside and outside paddle plating 110p, respectively, in a ring shape, the bonding strength between substrate 110 and encapsulant 150 at these locations can be increased, and occurrences of delamination between paddle 112 and encapsulant 150 can be reduced or prevented. By including third dimples 113c on leads 111, substrate 110 can reduce the stress occurring during the singulation process, and the bonding strength with respect to encapsulant 150 can be increased to mitigate or prevent delamination between leads 111 and encapsulant 150.

The present disclosure includes reference to certain examples. It will be understood by those skilled in the art, however, that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

1. An electronic device, comprising:
a substrate comprising a first side and a second side opposite to the first side, wherein the substrate comprises dimples on the first side of the substrate;
an electronic component over the first side of the substrate;
an encapsulant over the first side of the substrate and covering a lateral side of the electronic component; and
a first interconnect in the encapsulant and coupled to the electronic component and the substrate.

2. The electronic device of claim 1, comprising a plating on the first side of the substrate, wherein the first interconnect is coupled to the plating.

3. The electronic device of claim 2, wherein the dimples are between the plating and the electronic component.

4. The electronic device of claim 2, wherein the plating is between the electronic component and the dimples.

5. The electronic device of claim 1, wherein the dimples are at an outer periphery of the substrate.

6. The electronic device of claim 1, wherein the dimples are arranged in a ring pattern on the first side of the substrate.

7. The electronic device of claim 1, wherein the dimples are arranged in a row pattern or a column pattern.

8. The electronic device of claim 1, wherein the dimples are located on a first portion of the first side of the substrate, and a second portion of the first side of the substrate is free of the dimples.

9. The electronic device of claim 1, wherein the dimples have widths comprising a width range, and the dimples have pitches comprising a pitch range, wherein the width range is the same as the pitch range.

10. An electronic device, comprising:
a substrate comprising a first side and a second side opposite to the first side, a paddle, and a lead, wherein the substrate comprises dimples on the first side of the substrate;
an electronic component over the first side of the substrate over the paddle;
an encapsulant over the first side of the substrate and covering a lateral side of the electronic component; and
a first interconnect in the encapsulant and coupled to the electronic component and the lead.

11. The electronic device of claim 10, wherein:
the lead comprises a lead inward terminal, and a lead plating on the lead inward terminal; and
the first interconnect is coupled to the lead inward terminal at the lead plating.

12. The electronic device of claim 11, wherein the dimples are on the lead inward terminal adjacent to the lead plating.

13. The electronic device of claim 10, comprising:
a second interconnect in the encapsulant coupled to the electronic component and the paddle, wherein:
the paddle comprises a paddle inward terminal and a paddle plating on the paddle inward terminal; and
the second interconnect is coupled to the paddle inward terminal at the paddle plating.

14. The electronic device of claim 13, wherein:
the dimples comprise first dimples and second dimples, wherein the first dimples are between the paddle plating and the electronic component; and
wherein the paddle plating is between the first dimples and the second dimples.

15. The electronic device of claim 14, wherein:
the substrate comprises a tie bar; and
the second dimples are on the tie bar.

16. The electronic device of claim 10, wherein the dimples are located on a first portion of the first side of the substrate, and a second portion of the first side of the substrate is free of the dimples.

17. A method to manufacture an electronic device, comprising:
providing a substrate comprising a first side and a second side opposite to the first side;
etching dimples on the first side of the substrate, wherein the dimples are located on a first portion of the first side of the substrate, and a second portion of the first side of the substrate is free of the dimples;
attaching an electronic component to the first side of the substrate;
providing a first interconnect coupled to the electronic component and the substrate; and
providing an encapsulant over the first side of the substrate and covering a lateral side of the electronic component.

18. The method of claim 17, comprising:
providing a plating on the first side of the substrate, wherein the first interconnect is coupled to the plating.

19. The method of claim 18, wherein:
the dimples comprise first dimples and second dimples:
the first dimples are between the electronic component and the plating; and
the plating is between the first dimples and the second dimples.

20. The method of claim 17, wherein the dimples are at an outer periphery of the substrate.
